(19) United States
(12) Patent Application Publication
(10) Pub. No.: US 2013/0037076 A1
(43) Pub. Date: Feb. 14, 2013

(54) SOLAR PANEL AND ELECTRODE STRUCTURE THEREOF AND MANUFACTURING METHOD THEREOF

(71) Applicants: Keh-Yao WANG, Tainan City (TW); Kuo-Shih Liu, Taipei City (TW)

(72) Inventors: Keh-Yao WANG, Tainan City (TW); Kuo-Shih Liu, Taipei City (TW)

(73) Assignee: Gloria Solar Co., Ltd., Tainan City (TW)

(21) Appl. No.: 13/570,802

(22) Filed: Aug. 9, 2012

(30) Foreign Application Priority Data
Aug. 9, 2011 (TW) 100128419

(51) Int. Cl. H01L 31/05; H01L 31/18

(52) U.S. Cl. 136/244; 438/80; 257/E31.124

(57) ABSTRACT

A solar panel and an electrode structure thereof and a manufacturing method thereof are provided. The electrode structure comprises a first conductive structure and a second conductive structure. The first conductive structure is electrically connected to a plurality of first pole contacts of a first solar cell. The second conductive structure is connected to the first conductive structure, and the first and the second conductive structures are substantially extended along a line. The second conductive structure is electrically connected to a plurality of second pole contacts of a second solar cell.

### BACKGROUND OF THE INVENTION

1. Field of the Invention

The invention relates in general to a solar panel and an electrode structure thereof and a manufacturing method thereof, and more particularly to a solar panel and an electrode structure thereof and a manufacturing method thereof which are capable of shortening the electric transmission path.

2. Description of the Related Art

The conventional solar cell comprises a semiconductor structure, a first conductive structure and a second conductive structure. The first and the second conductive structures respectively have positive and negative polarity contacts disposed thereon or respectively have negative and positive polarity contacts disposed thereon. In a back contact solar cell, the first and the second conductive structures are formed on one side of the semiconductor structure. When the light radiates on the solar cell, the semiconductor structure generates a current flowing between the first and the second conductive structures.

However, the first conductive structure is connected to the second conductive structure at an angle (such as 90 degrees). In the course of flowing to the second conductive structure from the first conductive structure, the current has to pass through a big bending, and the current transmission path is thus lengthened.

### SUMMARY OF THE INVENTION

The invention is directed to a solar panel, an electrode structure thereof and a manufacturing method thereof which are capable of shortening the electric transmission path.

According to an embodiment of the present invention, an electrode structure is provided. The electrode structure comprises a first conductive structure and a second conductive structure. The first conductive structure is electrically connected to a plurality of first pole contacts of a first solar cell. The second conductive structure is connected to the first conductive structure, and the first and the second conductive structures are substantially extended along a line. The second conductive structure is electrically connected to a plurality of second pole contacts of a second solar cell.

According to another embodiment of the present invention, a solar panel is provided. The solar panel comprises a first solar cell, a second solar cell, and an electrode structure. The first solar cell has a plurality of first pole contacts and a plurality of second pole contacts, another first conductive structure and another second conductive structure. The second solar cell has a plurality of first pole contacts and a plurality of second pole contacts. The electrode structure comprises a first conductive structure and a second conductive structure. The first conductive structure is electrically connected to a plurality of first pole contacts of a first solar cell. The second conductive structure is connected to the first conductive structure, and the first and the second conductive structures are substantially extended along a line. The second conductive structure is electrically connected to a plurality of second pole contacts of a second solar cell. The another first conductive structure is electrically connected to the first pole contacts of the second solar cell. The another second conductive structure is electrically connected to the second pole contacts of the first solar cell.

According to an alternate embodiment of the present invention, a manufacturing method of a solar panel is provided. The manufacturing method comprises the following steps: An electrode structure is provided, wherein the electrode structure comprises a first conductive structure and a second conductive structure connected to the first conductive structure, and the first and the second conductive structures are substantially extended along a line. A first solar cell is connected to the electrode structure, wherein the first solar cell has a plurality of first pole contacts, and the first conductive structure is electrically connected to the first pole contacts of the first solar cell. A second solar cell is rotated, wherein the second solar cell has a plurality of second pole contacts. The second solar cell is connected to the electrode structure and is electrically connected to the second pole contacts of the second solar cell.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a top view of a solar panel according to an embodiment of the invention;

FIG. 2 shows a partial enlargement of a portion 2′ of FIG. 1;

FIG. 3A shows a cross-sectional view along a direction 3A-3A′ of FIG. 2;

FIG. 3B shows a top view of a first solar cell of FIG. 3A;

FIG. 4 shows a top view of an electrode structure according to another embodiment;

FIG. 5 shows a top view of an electrode structure according to an alternate embodiment;

FIG. 6 shows a top view of an electrode structure according to another alternate embodiment;

FIG. 7 shows a distribution diagram of the first and the second pole contacts viewed along a top-view direction of FIG. 3A;

FIG. 8 shows a top view of the distribution of first and second pole contacts of a solar cell according to another embodiment;

FIG. 9A shows a top view of the distribution of first and second pole contacts of a solar cell according to an alternate embodiment;

FIG. 9B shows a top view of an electrode structure corresponding to a solar cell of FIG. 9A;

FIG. 10A shows a top view of a solar cell according to other embodiment;

FIG. 10B shows a top view of an electrode structure corresponding to a solar cell of FIG, 10A;

FIGS. 11-14 show a manufacturing process of a solar panel of FIG. 1.

### DETAILED DESCRIPTION OF THE INVENTION

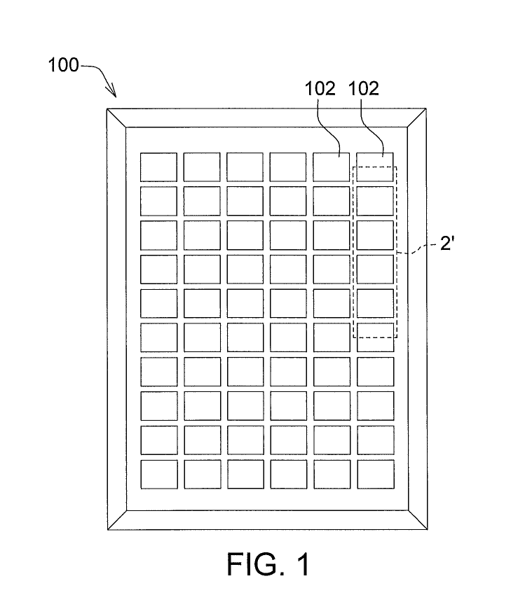

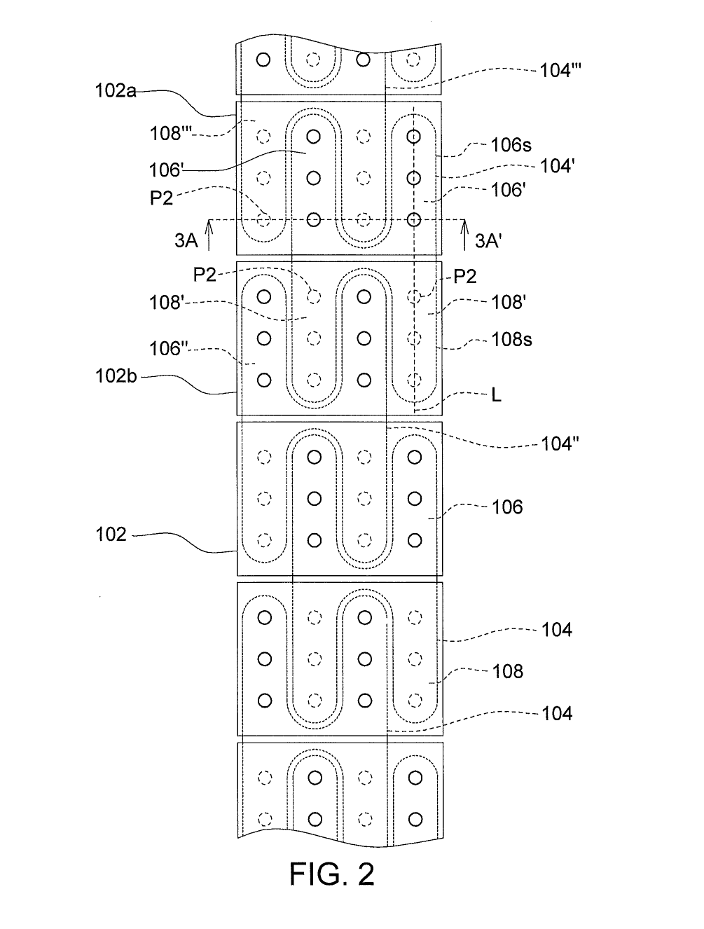

Referring to FIGS. 1 and 2. FIG. 1 shows a top view of a solar panel according to an embodiment of the invention. FIG. 2 shows a partial enlargement of a portion 2′ of FIG. 1. The solar panel 100 comprises a plurality of solar cells 102 and a plurality of electrode structures 104. Any two of the solar cells 102 may be identical to or different from each other. Examples of the solar cells 102 include interdigitated back contact (IBC) type, emitter wrap through (EWT) type or metalization wrap through (MWT) type.

As indicated in FIG. 2, two adjacent solar cells 102 are electrically connected in serial by an electrode structure 104. The way of serial connection increases the output voltage of the solar panel 100.

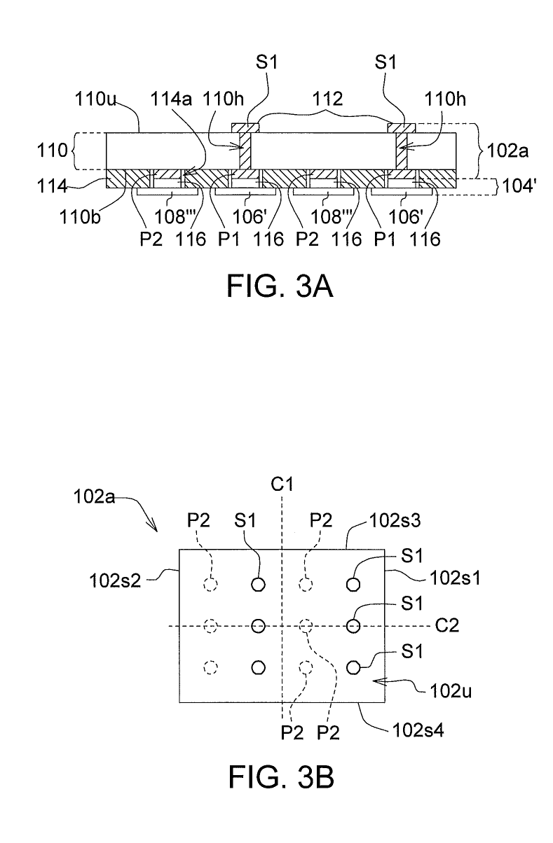

The structure of solar cell 102 is exemplified by the first solar cell 102a of FIG. 2 with an accompanying drawing FIG. 3A.

Referring to both FIG. 3A, a cross-sectional view along a direction 3A-3A′ of FIG. 2 is shown. The first solar cell 102a comprises a semiconductor structure 110, a plurality of first pole contacts P1, a plurality of second pole contacts P2 and a patterned trace 112. The semiconductor structure 110 comprises an N-type semiconductor (not illustrated) and a P-type semiconductor (not illustrated). The semiconductor structure 110 has a plurality of through holes 110h, a top surface 110u and a bottom surface 110b opposite to the top surface 110u, The first pole contacts P1 and the second pole contacts P2 are both adjacent to the bottom surface 110b. In the present embodiment, the electrodes (the first and the second pole contacts P1 and P2) are both adjacent to a back side (the bottom surface 110b) of the first solar cell 102a and form a back contact solar cell. The structures of other solar cells 102 are similar to that of the first solar cell 102a, and the similarities are not repeated here.

The patterned trace 112 is adjacent to the top surface 110u of the first solar cell 102a, and passes through the through holes 110h to be connected to the first pole contacts P1.

Referring to both FIG. 3A and FIG. 3B. FIG. 3B shows a top view of a first solar cell of FIG. 3A. As indicated in FIG. 3A, the patterned trace 112 comprises a plurality of importing contacts Si and a tree structure (not illustrated). The tree structure is formed on the top surface 110u and converges at the importing contacts S1. The importing contacts S1 extend to the first pole contacts P1 via the through holes 110h.

As indicated in FIG. 3B, the importing contacts S1 form an asymmetric distribution. For example, the importing contacts S1 form an asymmetric distribution with respect to a reference C1 such as the middle position between a first side 102s1 and a second side 102s2 of the first solar cell 102a or an asymmetric reference base. The first side 102s1 and the second side 102s2 are opposite to each other. In addition, the importing contacts S1 form an asymmetric distribution with respect to a reference C2 such as the middle position between a third side 102s3 and a fourth side 102s4 of the first solar cell 102a or an asymmetric reference line base. The third side 102s3 and the fourth side 102s4 are opposite to each other.

The patterned trace 112 may be electrically connected to the N-type semiconductor of the semiconductor structure 110, so that the first pole contacts P1 become the negative polarity of the first solar cell 102a. The second pole contacts P2 may he electrically connected to the P-type semiconductor of the semiconductor structure 110 and become the positive polarity of the first solar cell 102a. In other embodiments, under the circumstance that the structure of the semiconductor structure 110 changes or the connection relationship between the first and the second pole contacts P1 and P2 and the P-type and the N-type semiconductors changes, the first pole contacts P1 may become the positive polarity of the first solar cell 102a and the second pole contacts P2 may the become negative polarity of the first solar cell 102a.

As indicated in FIG. 3A, the solar panel 100 further comprises 114 disposed between the first solar cell 102a and the electrode structure 104′ for bonding the first solar cell 102a and the electrode structure 104′ together. Here, the film 114 may he realized by such as an EVA (Ethylene/Vinyl/Acetate) film. The film 114 may also be used for bonding other solar cells 102 and the electrode structure 104 together. In addition, the film 114 may have a plurality of through holes 114a via which the first and the second pole contacts P1 and P2 electrically contact the electrode structure 104. The electrode structure 104′ may comprise a plurality of electric contacts 116. The first and the second pole contacts P1 and P2 electrically contact the electric contacts 116 of the electrode structure 104. The electric contacts 116 may be realized by such as solder paste.

The structure of the electrode structure is exemplified by electrode structure 104′. The electrode structure 104′ may be realized by such as a conductive plate, a conductive piece, a conductive film or a conductive layer.

Returning to FIG. 2, the electrode structure 104′ comprises at least one first conductive structure 106′ and at least one second conductive structure 108′. The first conductive structure 106′ is electrically connected to a plurality of first pole contacts P1 (illustrated in FIG. 3A) of the first solar cell 102a. The second conductive structure 108′ is connected to the first conductive structure 106′. The second conductive structure 108′ and the first conductive structure 106′ substantially extend along a straight line L. Here, the straight line L is a non-bending path or a straight path. The second conductive structure 108′ is electrically connected to a plurality of second pole contacts P2 of the second solar cell 102b. In comparison to the curved path or the path having at least one bending, the straight path has the fastest electric transmission rate because the second conductive structure 108 and the first conductive structure 106 substantially extend along the straight line L, and the path of the current flowing form positive polarity to the negative polarity is the shortest or the path of electrons flowing from negative polarity to the positive polarity is the shortest.

As indicated in FIG. 2, the another first conductive structure 106″ of another electrode structure 104″ is electrically connected to the first pole contacts P1 (not illustrated in FIG. 2) of the second solar cell 102b, while the another second conductive structure 108′″ of the another electrode structure 104′″ is electrically connected to the second pole contacts P2 of the first solar cell 102a. In the present embodiment, the connection relationship between the other two adjacent solar cells 102 and their corresponding electrode structures 104 is similar to the connection relationship between the first and the second solar cells 102a and 102b and the electrode structure 104′, and the similarities are not repeated here.

The second conductive structure 108 and the first conductive structure 106 may be realized by a continuous structure formed in one piece. For example, the second conductive structure 108 and the first conductive structure 106 are formed in the same manufacturing process such as a cutting process.

As indicated in FIG. 2, the first conductive structure 106 has a cutting side 106s, and the second conductive structure 108 also has a cutting side 108s. Furthermore, the electrode structure 104 may be formed by one single electric film by using a cutter or by laser cutting technology, and the electrode structure 104 having been cut has a cutting side. The electric film may be formed by a material selected from a group consisting of copper, aluminum, gold or a combination thereof. In comparison to the conventional chemical etching process, the cutting process used in the present embodiment for cutting the electrode structure 104 incurs less manufacturing time, cost and pollution, and is more environmental friendly. In other implementations, the electrode structure 104 may be formed by way of etching.

The first and the second conductive structures of the electrode structure are symmetric in a top-down manner and/or a left-right manner.

As indicated in FIG. 2, let the electrode structure 104′ be taken for example. The first and the second conductive structures 106′ and 108′ of the electrode structure 104′ form a symmetric structure. Under the circumstance that the first and the second conductive structures 106′ and 108″ form a symmetric structure, the two adjacent electrode structures 104′ having been cut may be staggered and easily separated along the direction of a plane, such as the disposition plane of the first and the second pole contacts P1 and P2. Furthermore, the first and the second conductive structures of the conventional electrode structure intersect at an angle and interfere (engaged) with each other along the direction of the disposition plane, and cannot be separated. In addition, the first and the second conductive structures 106′ and 108′ of the electrode structure 104′ are not limited to a symmetric structure, and may form an asymmetric structure under the circumstance that the first and the second conductive structures 106′ and 108′ of the electrode structure 104′ are electrically connected to the solar cell 102.

The structural appearance of the first and the second conductive structures has many ways of implementation, and is not limited to the exemplifications of the embodiments of the invention.

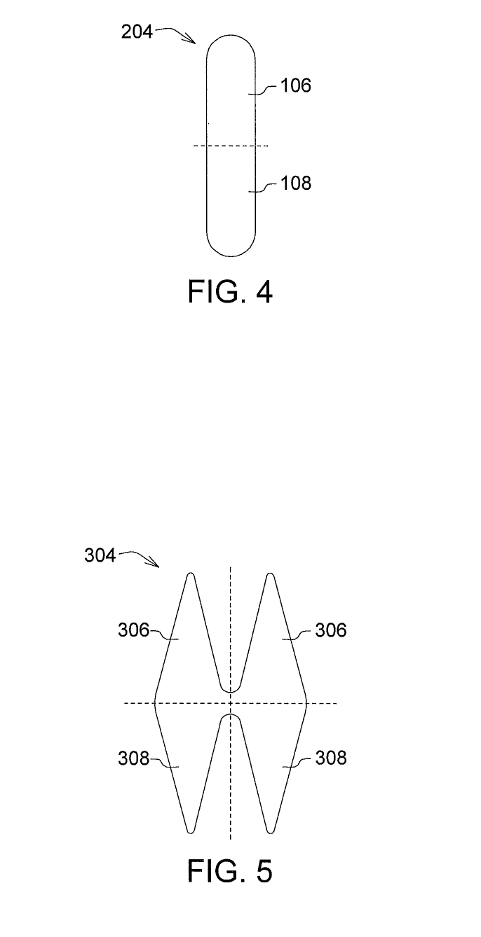

Referring to FIG. 4, a top view of an electrode structure according to another embodiment is shown. The electrode structure 204 only comprises one single first conductive structure 106 and one single second conductive structure 108.

Referring to FIG. 5, a top view of an electrode structure according to an alternate embodiment is shown. The electrode structure 304 comprises at least one first conductive structure 306 and at least one second conductive structure 308. The shapes of the first conductive structure 306 and the second conductive structure 308 are similar to a triangle.

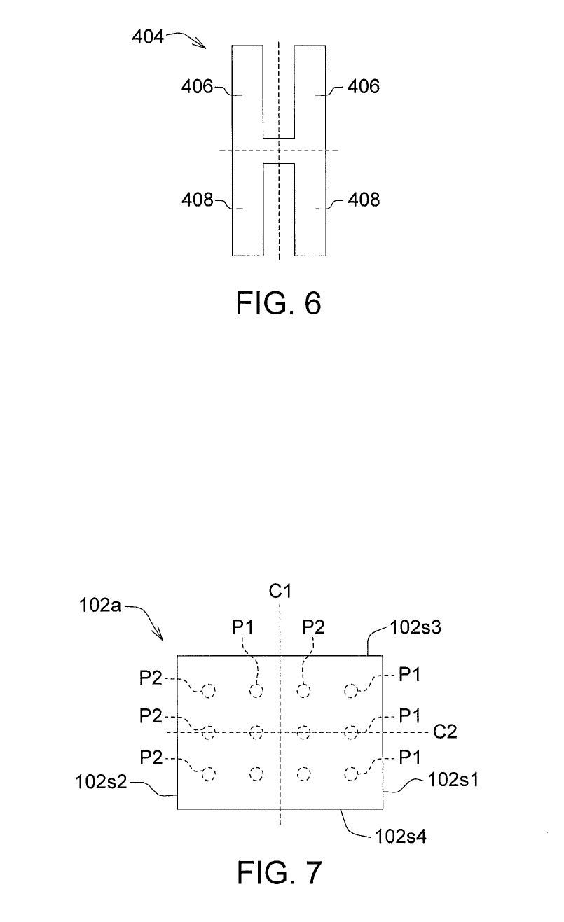

Referring to FIG. 6, a top view of an electrode structure according to another alternate embodiment is shown. The electrode structure 404 comprises at least one first conductive structure 406 and at least one second conductive structure 408. The shapes of the first conductive structure 406 and the second conductive structure 408 are a rectangle. In other embodiments, the appearance of the electrode structure may have other shapes.

The distribution of the first and the second pole contacts P1 and P2 of the solar cell 102 according to an embodiment of the invention is not limited to the symmetric distribution disclosed above, and may also be asymmetric with respect to the solar cell 102. Other electrode structures 202 and 302 are similar to the electrode structures 204 and 304.

The first and the second pole contacts of the solar cell form an asymmetric distribution. The first solar cell 102a is exemplified below with accompany drawing FIG. 7.

Referring to FIG. 7, a distribution diagram of the first and the second pole contacts viewed along a top-view direction of FIG. 3A is shown. The first pole contacts P1 and the second pole contacts P2 form an asymmetric distribution with respect to the reference C1. That is, the first and the second pole contacts P1 and P2 located to the left of the reference C1 are asymmetric with the first and the second pole contacts P1 and P2 located to the right of the reference C2. The first pole contacts P1 and the second pole contacts P2 form an asymmetric distribution with respect to the reference C2. That is, the first and the second pole contacts P1 and P2 located to the left of the reference C2 are asymmetric with the first and the second pole contacts P1 and P2 located to the right of the reference C2. In addition, the asymmetric distribution of the through holes 110h (illustrated in FIG. 3A) may correspond to the asymmetric distribution of the first and the second pole contacts P1 and P2.

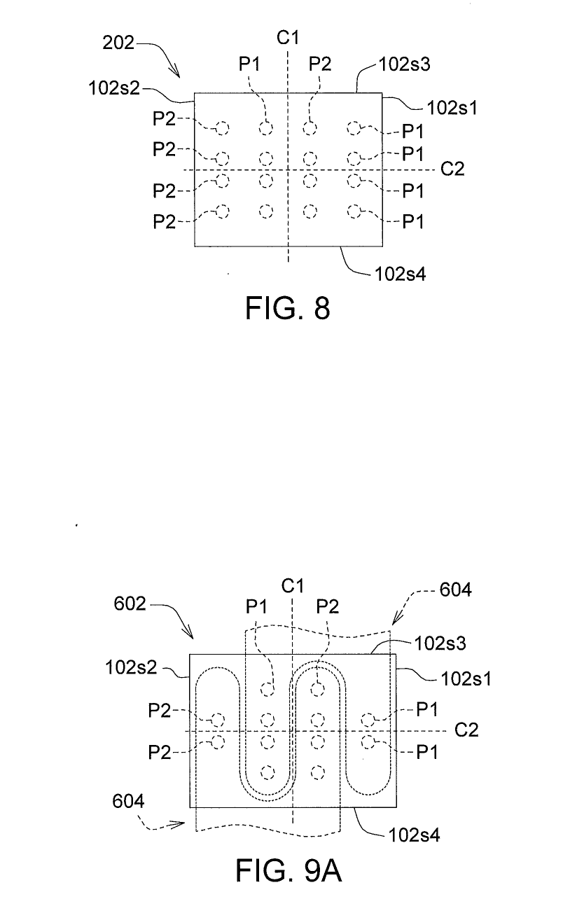

In another embodiment, the first and the second pole contacts P1 and P2 may form a symmetric distribution. Let FIG. 8 be taken for example below.

Referring to FIG. 8, a top view of the distribution of first and second pole contacts of a solar cell according to another embodiment is shown. In the solar cell 202, the first and the second pole contacts P1 and P2 form a symmetric distribution with respect to the reference C2.

Referring to FIG. 9A, a top view of the distribution of first and second pole contacts of a solar cell according to an alternate embodiment is shown. In the solar cell 602, the first and the second pole contacts P1 and P2 form a symmetric distribution with respect to the reference C2.

Referring to FIG. 9B, a top view of an electrode structure corresponding to a solar cell of FIG. 9A is shown. The electric contacts 116 of the electrode structure 604 are symmetric in a top-down manner but are asymmetric in a left-right manner.

In another embodiment, the first and the second pole contacts of the solar cell may also form an asymmetric distribution.

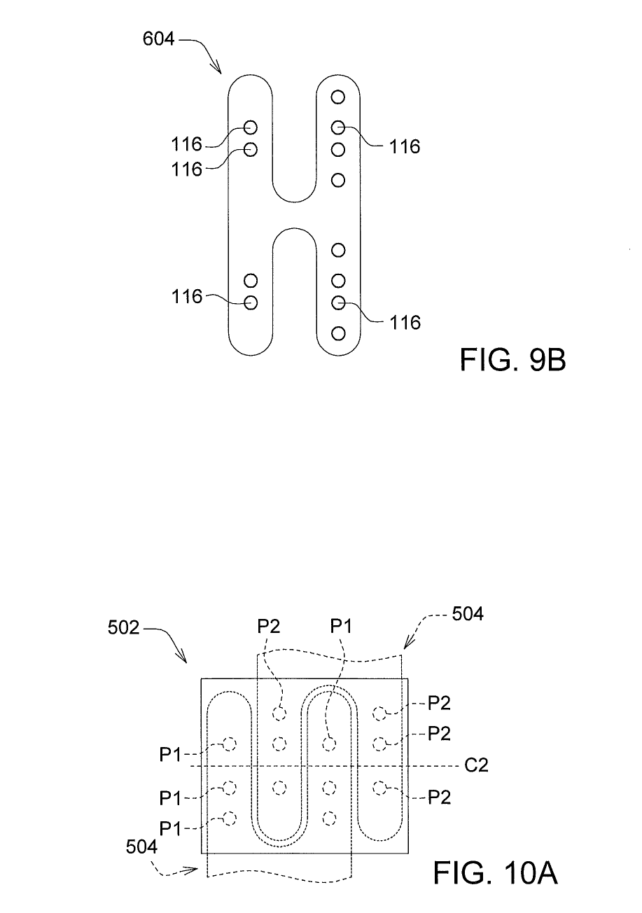

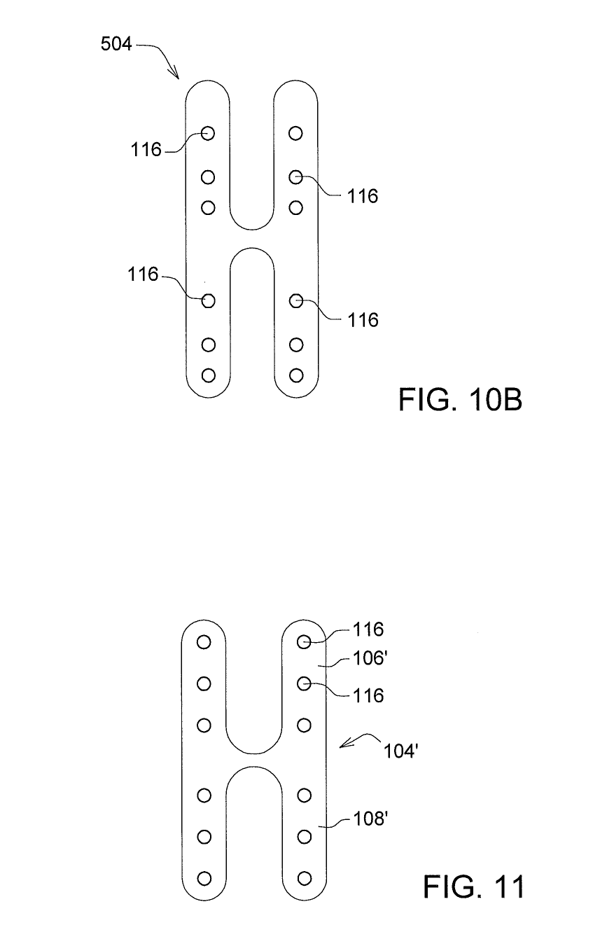

Referring to FIG. 10A, a top view of a solar cell according to other embodiment is shown. A plurality of first pole contacts P1 and a plurality of second pole contacts P2 of solar cell 504 form an asymmetric distribution with respect to the reference 02.

Referring to FIG. 10B, a top view of an electrode structure corresponding to a solar cell of FIG. 10A is shown. The electric contacts 116 of the electrode structure 504 are asymmetric in a top-down manner but are symmetric in a left-right manner.

In another embodiment, a plurality of first pole contacts P1 and a plurality of second pole contacts P2 of the solar cell may form other forms of asymmetric distribution with respect to the reference C2, and the associated electric contacts 116 of the electrode structure may also form an asymmetric distribution or a symmetric distribution correspondingly.

The following descriptions are accompanied with FIGS. 11˜14 which show a manufacturing process of a solar panel of FIG. 1. Let the disposition of the electrode structure 104′ of the electrode structures 104 be taken for example.

As indicated in FIG. 11, an electrode structure 104′ comprising a first conductive structure 106 and a second conductive structure 108′ is provided, wherein the electrode structure 108′ is connected to the first conductive structure 106′. The electrode structure 104′ may be formed by way of cutting such as by using a cutter or by laser cutting technology.

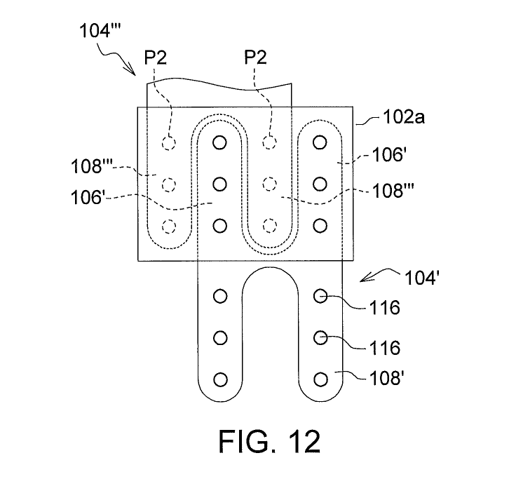

Next, as indicated in FIG. 12, the first solar cell 102a of FIG. 3B is connected to the electrode structure 104′ of FIG. 11, wherein the first conductive structure 106′ of the electrode structure 104′ corresponds to the first pole contacts P1 (illustrated in FIG. 4) of the first solar cell 102a for electrically connecting the first pole contacts P1, while the second conductive structure 106″ of the electrode structure 104″ corresponds to the second pole contacts P2 of the first solar cell 102a for electrically connecting the second pole contacts P2. In addition, the two adjacent conductive structures, that is, the first and the second conductive structures, are staggered with each other. For example, the conductive structure adjacent to the first conductive structure 106′ is the second conductive structure 108′″, while the conductive structure adjacent to the second conductive structure 108′″ is the first conductive structure 106′.

The first solar cell may be disposed by way of at least one of rotation and translation so that the first solar cell is connected to the electrode structure. For example, before the first solar cell 102a is connected to the electrode structure 104, the first solar cell 102a may be rotated by such as 180 degrees, so that the first pole contacts P1 (illustrated in FIG. 4) of the first solar cell 102a corresponds to the first conductive structure 106′ of the electrode structure 104′. In addition, the rotation angle of the first solar cell 102a is not for limiting the invention. In an embodiment, under the circumstance that the first solar cell 102a is the firstly disposed solar cell, the first solar cell 102a may be translated but not rotated. To summarize, the first solar cell 102a may be disposed by way of at least one of rotation and translation.

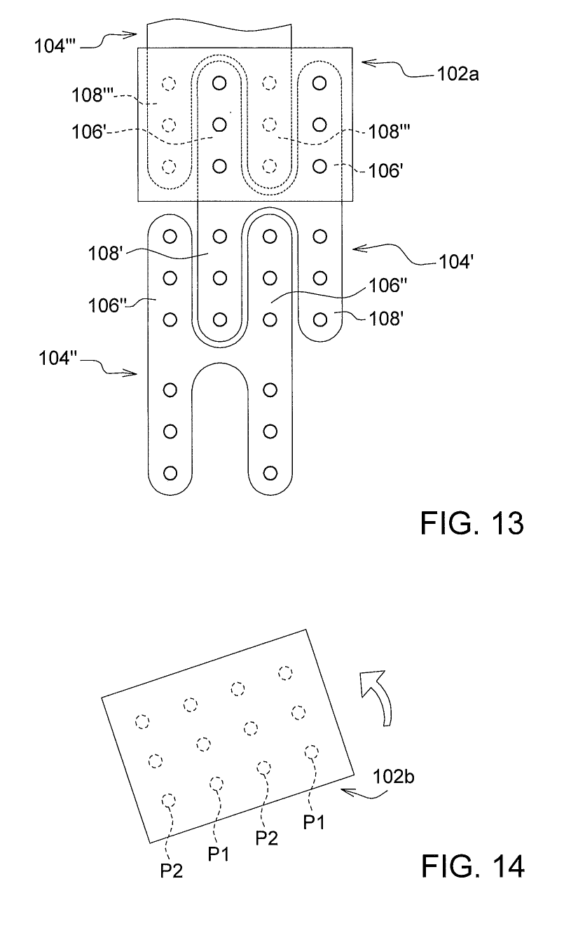

Then, as indicated in FIG. 13, the next electrode structure 104″ is disposed by such as translation without rotation, wherein, the electrode structure 104 is adjacent to the electrode structure 104′. That the electrode structure is disposed by way of translation reduces the complicity in the design of the operating machine. For example, the rotation mechanism of the rotation of the mechanic arm can be omitted or simplified.

In addition, the disposition of the electrode structure is not limited to translation. In other embodiments of the invention, the electrode structure 104″ may be disposed by way of rotation, wherein the rotation angle is such as an integral multiple of 180 degrees. For example, when the solar cell 602 (FIG. 9A) is used, the next electrode structure 604 (FIG. 9B) may be rotated by an integral multiple of 180 degrees surrounding the disposition plane, so that the difference between the distribution direction of the electric contacts 116 of the rotated electrode structure 604 after rotation and that of the electric contacts 116 of the previous electrode structure 604 is 180 degrees. Or, when the solar cell 502 (FIG. 10A) is used, the next electrode structure 504 (FIG. 10B) may he rotated by an integral multiple of 180 degrees surrounding the disposition plane, so that the difference between the distribution direction of the electric contacts 116 of the rotated electrode structure 504 and that of the electric contacts 116 of the previous electrode structure 504 is 180 degrees.

Or, the electrode structure may be disposed by way of both translation and rotation.

The disposition orientations of two adjacent electrode structures (such as the electrode structure 104 and the electrode structure 104″) are substantially the same. That is, the distribution relationships of the electric contacts of two adjacent electrode structures after disposition are almost or exactly the same. Besides, the two adjacent electrode structures may be staggered from each other. As indicated in FIG. 13, the electrode structure 104′ is disposed to the right with respect to the electrode structure 104″; the electrode structure 104″ is disposed to the left with respect to the electrode structure 104′. Through the above disposition principles, the disposition sequence (from left to right) of the conductive structure corresponding to two adjacent solar cells changes to the sequence of the first conductive structure 106″→the second conductive structure 108′→the first conductive structure 106″→the second conductive structure 108′ from the sequence of the second conductive structure 108′″→the first conductive structure 106′→the second conductive structure 108′″→the first conductive structure 106. The “left-right direction” can be said to he the direction perpendicular to the extending direction of the first or the second conductive structure” (that is, the left-right direction as indicated in FIG. 13.

In other embodiments, the disposition of the next electrode structure can be omitted. For example, after the last solar cell is connected to the electrode structure, there is no need for the disposition of the next electrode structure.

Then, the second solar cell 102b is connected to the electrode structure 104′, and the second solar cell 102b and the electrode structure 104′ are indicated in FIG. 2. The second conductive structure 108′ of the electrode structure 104′ is electrically connected to the second pole contacts P2 of the second solar cell 102b, while the first conductive structure 106″ of the electrode structure 104″ is electrically connected to the first pole contacts P1 (not illustrated in FIG. 2) of the second solar cell 102b.

The second solar cell may be disposed by way of at least one of rotation and translation, so that the second solar cell is connected to the electrode structure. In the following exemplification, the second solar cell is rotated.

As indicated in FIG. 14, the second solar cell 102b is rotated by such as 180 degrees. The rotated second solar cell 102b is such as the second solar cell 102b of FIG. 2. The first and the second pole contacts P1 and P2 of the translated second solar cell 102b respectively correspond to the first conductive structure 106″ of the electrode structure 104 and the second conductive structure 108′ of the electrode structure 104′. Furthermore, since the disposition sequence of the two adjacent electrode structures (such as electrode structures 104′ and 104″) changes, under the circumstance that the difference between the disposition orientations of the two adjacent solar cells is 180 degrees (surrounding the surrounding the disposition plane), the first and the second pole contacts P1 and P2 of the rotated solar cell 102b respectively correspond to the first conductive structure 106″ of the electrode structure 104″ and the second conductive structure 108′ of the electrode structure 104′, Although the disposition of the second solar cell 102b of the present embodiment is exemplified by rotation, the invention is not limited thereto. Either translation or rotation would do as long as the disposition orientations of two adjacent solar cells are different and form an angle.

In an implementation, the initial disposition of the second solar cell 102b is illustrated in FIG. 4, and after the second solar cell 102b FIG. 4 is rotated, the disposition is illustrated as the second solar cell 102b of FIG. 2. In other implementation, the second solar cell may also be disposed by way of translation. For example, the initial disposition of the second solar cell 102b is illustrated in FIG. 2. Under such circumstance, the second solar cell 102b may be disposed by way of translation instead of rotation, and the rotation step can thus be omitted. To summarize, the second solar cell 102b may be disposed by way of at least one of rotation and translation.

In addition, the disposition sequence of the electrode structure and the solar cell is not specified in the invention. In an embodiment, the solar cells 102 are disposed on corresponding electrode structures 104 one by one after the disposition of the electrode structure 104 is completed. Or, the electrode structures 104 are disposed on corresponding solar cells 102 one by one after the disposition of the solar cells 102 is completed. Or, the solar cells 102 and the electrode structures 104 may be alternately disposed. That is, at least one electrode structure 104 is disposed after at least one corresponding solar cell 102 is disposed. Or, at least one solar cell 102 is disposed after at least one corresponding electrode structure 104 is disposed.

In addition, before the electrode structure 104 is connected to the solar cell 102, the film 114 of FIG. 3A may be disposed on the electrode structure 104 or the solar cell 102 for bonding the electrode structure 104 and the solar cell 102 together.

To summarize, the first and the second pole contacts P1 and P2 of the solar cell may form a symmetric or an asymmetric distribution with respect to the reference C1, and the first and the second pole contacts P1 and P2 of the solar cell may form a symmetric or an asymmetric distribution with respect to the reference C2. The electric contacts 116 of the electrode structure may form a symmetric or an asymmetric distribution in association with the solar cell.

The solar panel, the electrode structure thereof and the manufacturing method thereof disclosed in the above embodiments of the invention have many features exemplified below.

1). Since the second conductive structure and the first conductive structure substantially extend along a straight line, the path of the current flowing form positive polarity to negative polarity is the shortest or the path of electrons flowing from negative polarity to positive polarity is the shortest. That is, the straight path has the fastest electric transmission rate.

2). Since the electrode structure may be formed by way of cutting, the manufacturing time and cost are reduced and environmental pollution is avoided.

3). Since the electrode structure may be realized by a symmetric structure, the two adjacent electrode structures 104′ having been cut may be staggered and easily separated along the direction of a plane

4). Since the first and the second pole contacts form an asymmetric distribution, the difference between the disposition orientations of the two adjacent solar cells is 180 degrees, and the assembly is hence improved.

5). The electrode structure may be disposed by way of translation without rotation.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electrode structure, comprising:
a first conductive structure electrically connected to a plurality of first pole contacts of a first solar cell; and
a second conductive structure connected to the first conductive structure and electrically connected to a plurality of second pole contacts of a second solar cell, wherein the first and the second conductive structures are substantially extended along a line.

2. The electrode structure according to claim 1, wherein the first and the second conductive structures form a symmetric structure.

3. The electrode structure according to claim 1, wherein each of the first and the second conductive structures has a cutting side.

4. A solar panel, comprising:
a first solar cell having a plurality of first pole contacts and a plurality of second pole contacts;
a second solar cell having a plurality of first pole contacts and a plurality of second pole contacts;
an electrode structure, comprising:
a first conductive structure electrically connected to the first pole contacts of the first solar cell; and
a second conductive structure connected to the first conductive structure and electrically connected to the second pole contacts of the second solar cell, wherein the first and the second conductive structures are substantially extended along a line;
another first conductive structure electrically connected to the first pole contacts of the second solar cell; and
another second conductive structure electrically connected to the second pole contacts of the first solar cell.

5. The solar panel according to claim 4, wherein the first and the second conductive structures form a symmetric structure.

6. The solar panel according to claim 4, wherein the second conductive structure and the another first conductive structure are adjacent to each other.

7. The solar panel according to claim 4, wherein each of the first and the second conductive structures has a cutting side.

8. The solar panel according to claim 4, wherein the first and the second pole contacts of at least one of the first and the second solar cells form an asymmetric distribution.

9. The solar panel according to claim 4, wherein the first and the second pole contacts of at least one of the first and the second solar cells form a symmetric distribution.

10. A manufacturing method of a solar panel, comprising:
providing an electrode structure comprising a first conductive structure and a second conductive structure connected to the first conductive structure, wherein the first and the second conductive structure are substantially extended along a line;
connecting the electrode structure to a first solar cell comprising a plurality of first pole contacts, wherein the first conductive structure is electrically connected to the first pole contacts of the first solar cell;
connecting the electrode structure to a second solar cell comprising a plurality of second pole contacts, wherein an angle is contained between the is first and the second solar cells, and the second conductive structure of the electrode structure is electrically connected to the second pole contacts of the second solar cell.

11. The manufacturing method according to claim 10, further comprising:
forming the electrode structure by way of cutting.

12. The manufacturing method according to claim 11, wherein the step of forming the electrode structure by way of cutting is performed with cutter or laser cutting.

13. The manufacturing method according to claim 10, wherein before the step of connecting the first solar cell and the electrode structure is performed, the manufacturing method further comprises:
rotating the first solar cell.

14. The manufacturing method according to claim 10, wherein before the step of connecting the second solar cell and the electrode structure is performed, the manufacturing method further comprises:
rotating the second solar cell.

15. The manufacturing method according to claim 14, wherein the step of rotating the second solar cell further comprises:
rotating the second solar cell by the angle.

16. The manufacturing method according to claim 15, wherein the angle is 180 degrees.

17. The manufacturing method according to claim 10, wherein before the step of connecting the first solar cell and the electrode structure is performed, the manufacturing method further comprises:
translating the first solar cell.

18. The manufacturing method according to claim 10, further comprising:
disposing another electrode structure adjacent to the electrode structure.

19. The manufacturing method according to claim 18, wherein the step of disposing the another electrode structure further comprises:
translating the another electrode structure.

20. The manufacturing method according to claim 18, wherein the step of disposing the another electrode structure further comprises:
rotating the another electrode structure by 180 degrees.
